(19) United States
(12) Patent Application Publication
(10) Pub. No.: US 2021/0202296 A1
(43) Pub. Date: Jul. 1, 2021

(54) METHOD FOR LIFTING SUBSTRATE AND APPARATUS FOR TREATING SUBSTRATE

(71) Applicant: SEMES CO., LTD., Chungcheongnam-do (KR)

(72) Inventors: Sukhwan CHI, Gyeonggi-do (KR); Kyo Sang YOON, Chungcheongnam-do (KR); Bo Hee LEE, Chungcheongnam-do (KR); Byoungdoo CHOI, Seoul (KR)

(73) Assignee: SEMES CO., LTD.

(21) Appl. No.: 17/138,427

(22) Filed: Dec. 30, 2020

(30) Foreign Application Priority Data
Dec. 30, 2019 (KR) 10-2019-0177478

(51) Int. Cl. H01L 21/687; H01L 21/67; H01L 21/677

(52) U.S. Cl. CPC H01L 21/68742; H01L 21/67763; H01L 21/67259

(57) ABSTRACT

A method for lifting a substrate includes raising the substrate off a support plate having the substrate placed thereon, by using a lift pin, in which the lift pin raises the substrate off the support plate while vertically moving between a lowered position spaced apart downward from the support plate by a first distance and a raised position spaced apart upward from the support plate by a second distance, and the lift pin is brought into contact with the substrate in an interval in which the lift pin is decelerated or moved at a constant velocity.

### CROSS-REFERENCE TO RELATED APPLICATIONS

A claim for priority under 35 U.S.C. § 119 is made to Korean Patent Application No. 10-2019-0177478 filed on Dec. 30, 2019, in the Korean Intellectual Property Office, the entire contents of which are hereby incorporated by reference.

### BACKGROUND

Embodiments of the inventive concept described herein relate to a substrate lifting method for raising a substrate off a support plate, and a substrate treating apparatus.

In general, to manufacture semiconductor elements, unit processes, such as deposition, coating, developing, etching, cleaning, and the like, are sequentially or repeatedly performed on a substrate. The processes are performed in different apparatuses, and a robot provided in a substrate treating apparatus transfers the substrate between the apparatuses. Furthermore, each of the apparatuses is equipped with a pin assembly for receiving the substrate from the robot or transferring the substrate to the robot. The pin assembly includes lift pins for receiving the substrate from the robot or transferring the substrate to the robot.

A support plate for supporting the substrate generally has pin holes vertically formed through the support plate. The lift pins are provided in the pin holes, respectively, and move upward and downward to seat the substrate on the support plate.

However, when the lift pins raise the substrate off the support plate, a squeeze effect phenomenon may arise in which the substrate is bounced or broken due to negative pressure instantaneously formed between the substrate and the support plate.

### SUMMARY

Embodiments of the inventive concept provide a substrate lifting method and a substrate treating apparatus for minimizing occurrence of a squeeze effect during operation of lift pins.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, a method for lifting a substrate includes raising the substrate off a support plate having the substrate placed thereon, by using a lift pin, in which the lift pin raises the substrate off the support plate while vertically moving between a lowered position spaced apart downward from the support plate by a first distance and a raised position spaced apart upward from the support plate by a second distance, and the lift pin is brought into contact with the substrate in an interval in which the lift pin is decelerated or moved at a constant velocity.

According to an embodiment, the raising of the substrate may include a first acceleration step of accelerating the lift pin at a first acceleration from a first velocity to a second velocity higher than the first velocity and a first deceleration step of decelerating the lift pin at a first deceleration from the second velocity to a third velocity lower than the second velocity, and the lift pin may be brought into contact with the substrate in the first deceleration step.

According to an embodiment, the raising of the substrate may include a first acceleration step of accelerating the lift pin at a first acceleration from a first velocity to a second velocity higher than the first velocity and a first constant velocity step of uniformly moving the lift pin at the second velocity, and the lift pin may be brought into contact with the substrate in the first constant velocity step.

According to an embodiment, the raising of the substrate may further include a first constant velocity step of uniformly moving the lift pin at the second velocity after the first acceleration step.

According to an embodiment, the raising of the substrate may further include a second acceleration step of accelerating the lift pin at a second acceleration from the third velocity to a fourth velocity higher than the third velocity after the first deceleration step and a second deceleration step of decelerating the lift pin at a second deceleration from the fourth velocity to a fifth velocity lower than the fourth velocity.

According to an embodiment, the raising of the substrate may further include a second constant velocity step of uniformly moving the lift pin at the fourth velocity.

According to an embodiment, the second acceleration may be greater than the first acceleration.

According to an embodiment, the first velocity may be 0.

According to an embodiment, the third velocity may be 0.

According to an embodiment, the fifth velocity may be 0.

According to an exemplary embodiment, an apparatus for treating a substrate includes a support plate on which the substrate is placed, a lift pin that loads the substrate onto the support plate or unloads the substrate from the support plate, a drive member that raises or lowers the lift pin, and a controller that controls operation of the drive member. The controller controls the drive member to raise the substrate off the support plate while vertically moving the lift pin between a lowered position spaced apart downward from the support plate by a first distance and a raised position spaced apart from upward from the support plate by a second distance and to bring the lift pin into contact with the substrate in an interval in which the lift pin is decelerated or moved at a constant velocity.

According to an embodiment, the controller may control the drive member to accelerate the lift pin at a first acceleration from a first velocity to a second velocity higher than the first velocity, uniformly move the lift pin at the second velocity, decelerate the lift pin at a first deceleration from the second velocity to a third velocity lower than the second velocity, and bring the lift pin into contact with the substrate when the lift pin is decelerated.

According to an embodiment, the controller may control the drive member to accelerate the lift pin at a second acceleration from the third velocity to a fourth velocity higher than the third velocity after decelerating the lift pin at the first deceleration, uniformly move the lift pin at the fourth velocity, and decelerate the lift pin at a second deceleration from the fourth velocity to a fifth velocity lower than the fourth velocity.

According to an embodiment, the second acceleration may be greater than the first acceleration.

According to an embodiment, the first velocity may be 0.

According to an embodiment, the third velocity may be 0.

According to an embodiment, the fifth velocity may be 0.

According to an embodiment, the drive member may be a motor.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic perspective view illustrating a substrate treating apparatus according to an embodiment of the inventive concept;

FIG. 2 is a sectional view illustrating coating blocks and developing blocks of the substrate treating apparatus of FIG. 1;

FIG. 3 is a plan view of the substrate treating apparatus of FIG. 1;

FIG. 4 is a view illustrating one example of a hand of a transfer robot of FIG. 3;

FIG. 5 is a plan view of a heat treatment chamber of FIG. 2;

FIG. 6 is a front view of the heat treatment chamber of FIG. 3;

FIG. 7 is a sectional view of a heating unit according to an embodiment of the inventive concept;

FIG. 8 is a flowchart illustrating a substrate lifting method according to an embodiment of the inventive concept;

FIG. 9 is a graph depicting a moving velocity of lift pins according to an embodiment of the inventive concept;

FIGS. 10 to 13 are views illustrating the substrate lifting method in sequence according to an embodiment of the inventive concept; and

FIGS. 14 to 18 are views illustrating a substrate lifting method in sequence according to another embodiment of the inventive concept.

### DETAILED DESCRIPTION

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of components are exaggerated for clarity of illustration.

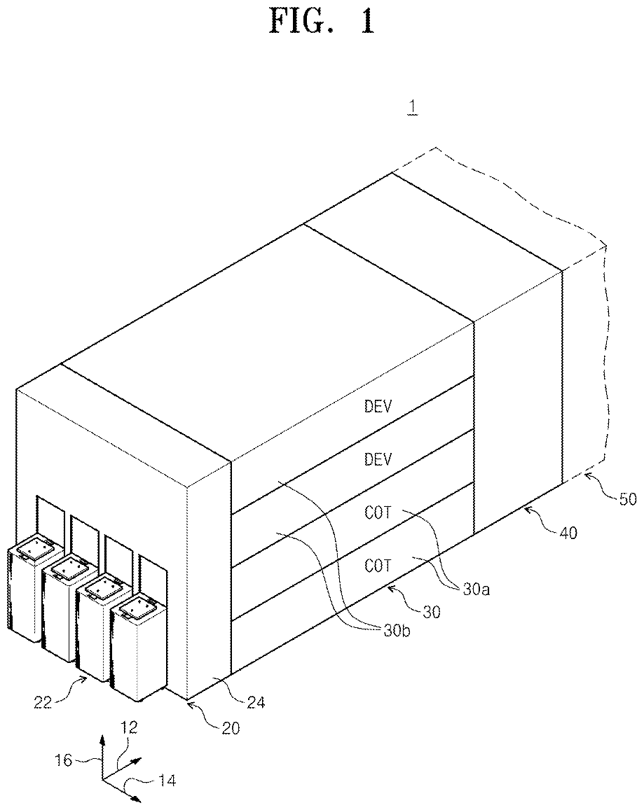

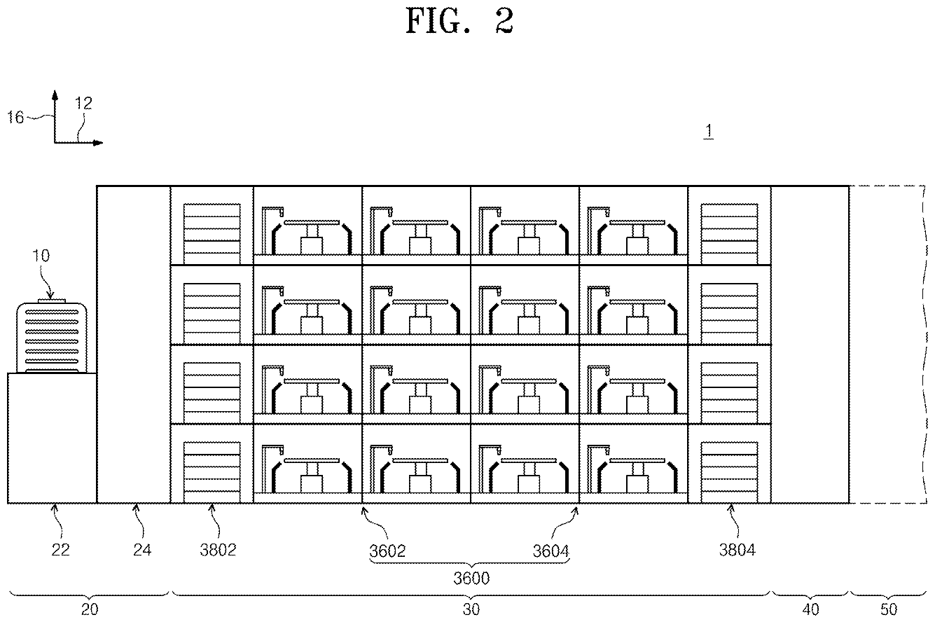

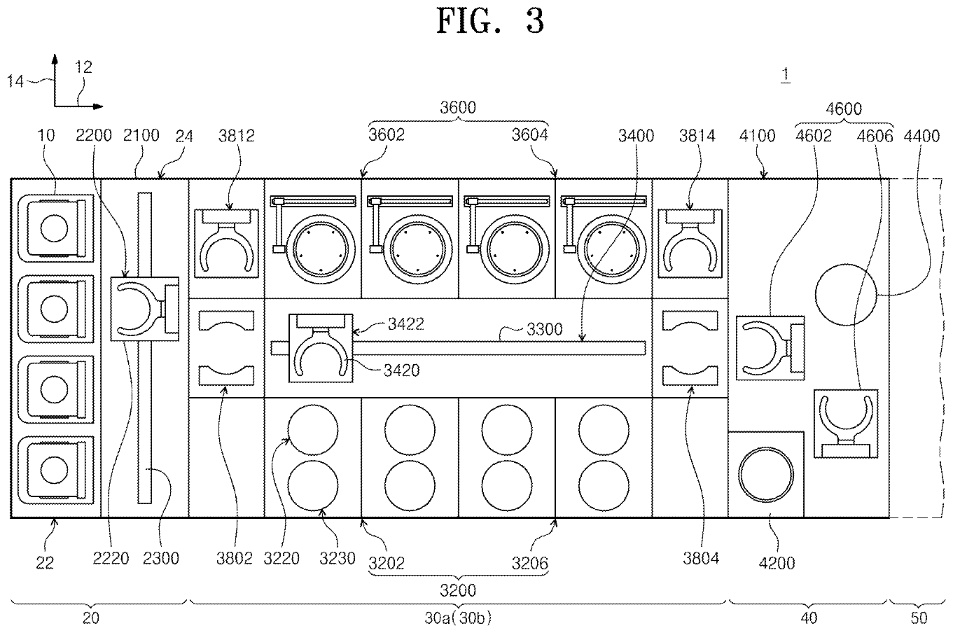

FIG. 1 is a schematic perspective view illustrating a substrate treating apparatus according to an embodiment of the inventive concept. FIG. 2 is a sectional view illustrating coating blocks and developing blocks of the substrate treating apparatus of FIG. 1. FIG. 3 is a plan view of the substrate treating apparatus of FIG. 1.

Referring to FIGS. 1 to 3, the substrate treating apparatus 1 includes an index module 20, a treating module 30, and an interface module 40. According to an embodiment, the index module 20, the treating module 30, and the interface module 40 are sequentially disposed in a row. Hereinafter, a direction in which the index module 20, the treating module 30, and the interface module 40 are arranged is referred to as a first direction 12, a direction perpendicular to the first direction 12 when viewed from above is referred to as a second direction 14, and a direction perpendicular to both the first direction 12 and the second direction 14 is referred to as a third direction 16.

The index module 20 transfers substrates W from carriers 10 having the substrates W received therein to the treating module 30 and places the completely treated substrates W in the carriers 10. The lengthwise direction of the index module 20 is parallel to the second direction 14. The index module 20 has load ports 22 and an index frame 24. The load ports 22 are located on the opposite side to the treating module 30 with respect to the index frame 24. The carriers 10, each of which has the substrates W received therein, are placed on the load ports 22. The load ports 22 may be disposed along the second direction 14.

Airtight carriers 10 such as front open unified pods (FOUPs) may be used as the carriers 10. The carriers 10 may be placed on the load ports 22 by a transfer unit (not illustrated), such as an overhead transfer, an overhead conveyor, or an automatic guided vehicle, or by an operator.

An index robot 2200 is provided in the index frame 24. A guide rail 2300, the lengthwise direction of which is parallel to the second direction 14, is provided in the index frame 24, and the index robot 2200 is movable on the guide rail 2300. The index robot 2200 includes hands 2220 on which the substrates W are placed. The hands 2220 are movable forward and backward, rotatable about an axis facing the third direction 16, and movable along the third direction 16.

The treating module 30 performs a coating process and a developing process on the substrates W. The treating module 30 has the coating blocks 30a and the developing blocks 30b. The coating blocks 30a perform the coating process on the substrates W, and the developing blocks 30b perform the developing process on the substrates W. The coating blocks 30a are stacked on each other. The developing blocks 30b are stacked on each other.

According to the embodiment of FIG. 1, two coating blocks 30a and two developing block 30b are provided. The coating blocks 30a may be disposed under the developing blocks 30b. According to an embodiment, the two coating blocks 30a may perform the same process and may have the same structure. Furthermore, the two developing blocks 30b may perform the same process and may have the same structure.

Referring to FIG. 3, each of the coating blocks 30a has heat treatment chambers 3200, a transfer chamber 3400, liquid treatment chambers 3600, and buffer chambers 3800. Each of the heat treatment chambers 3200 performs a heat treatment process on the substrate W. The heat treatment process may include a cooling process and a heating process. Each of the liquid treatment chambers 3600 forms a liquid film on the substrate W by dispensing a liquid onto the substrate W. The liquid film may be a photoresist film or an antireflection film. The transfer chamber 3400 transfers the substrate W between the heat treatment chamber 3200 and the liquid treatment chamber 3600 in the coating block 30a.

The transfer chamber 3400 is disposed such that the lengthwise direction thereof is parallel to the first direction 12. A transfer robot 3422 is provided in the transfer chamber 3400. The transfer robot 3422 transfers the substrate W between the heat treatment chamber 3200, the liquid treatment chamber 3600, and the buffer chambers 3800. According to an embodiment, the transfer robot 3422 has a hand 3420 on which the substrate W is placed, and the hand 3420 is movable forward and backward, rotatable about an axis facing the third direction 16, and movable along the third direction 16. A guide rail 3300, the lengthwise direction of which is parallel to the first direction 12, is provided in the transfer chamber 3400, and the transfer robot 3422 is movable on the guide rail 3300.

Some of the liquid treatment chambers 3600 may be stacked on each other. The liquid treatment chambers 3600 are disposed on one side of the transfer chamber 3400. The liquid treatment chambers 3600 are arranged side by side along the first direction 12. Some of the liquid treatment chambers 3600 are located adjacent to the index module 20. Hereinafter, these liquid treatment chambers are referred to as the front liquid treatment chambers 3602. Other liquid treatment chambers 3600 are located adjacent to the interface module 40. Hereinafter, these liquid treatment chambers are referred to as the rear liquid treatment chambers 3604.

Each of the front liquid treatment chambers 3602 applies a first liquid to the substrate W, and each of the rear liquid treatment chambers 3604 applies a second liquid to the substrate W. The first liquid and the second liquid may be different types of liquids. According to an embodiment, the first liquid is an antireflection film, and the second liquid is photoresist. The photoresist may be applied to the substrate W coated with the antireflection film. Selectively, the first liquid may be photoresist, and the second liquid may be an antireflection film. In this case, the antireflection film may be applied to the substrate W coated with the photoresist. Selectively, the first liquid and the second liquid may be of the same type. Both the first liquid and the second liquid may be photoresist.

Some of the buffer chambers 3800 are disposed between the index module 20 and the transfer chamber 3400. Hereinafter, these buffer chambers are referred to as the front buffers 3802. The front buffers 3802 are stacked on each other along an up/down direction. The other buffer chambers 3800 are disposed between the transfer chamber 3400 and the interface module 40. These buffer chambers are referred to as the rear buffers 3804. The rear buffers 3804 are stacked on each other along the up/down direction. Each of the front buffers 3802 and the rear buffers 3804 temporarily stores a plurality of substrates W. The substrates W stored in the front buffers 3802 are loaded or unloaded by the index robot 2200 and the transfer robot 3422. The substrates W stored in the rear buffers 3804 are loaded or unloaded by the transfer robot 3422 and a first robot 4602.

Each of the developing blocks 30b has heat treatment chambers 3200, a transfer chamber 3400, and liquid treatment chambers 3600. The heat treatment chambers 3200, the transfer chamber 3400, and the liquid treatment chambers 3600 of the developing block 30b are provided in a structure and an arrangement substantially similar to the structure and the arrangement in which the heat treatment chambers 3200, the transfer chamber 3400, and the liquid treatment chambers 3600 of the coating block 30a are provided. However, the liquid treatment chambers 3600 in the developing block 30b are provided as developing chambers 3600, all of which identically perform a developing process on the substrate W by dispensing a developing solution onto the substrate W.

The interface module 40 connects the treating module 30 with an external exposing apparatus 50. The interface module 40 has an interface frame 4100, an additional process chamber 4200, an interface buffer 4400, and a transfer member 4600.

The interface frame 4100 may have, at the top thereof, a fan filter unit that forms a downward air flow in the interface frame 4100. The additional process chamber 4200, the interface buffer 4400, and the transfer member 4600 are disposed in the interface frame 4100. Before the substrate W completely treated in the coating block 30a is transferred to the exposing apparatus 50, the additional process chamber 4200 may perform a predetermined additional process on the substrate W. Selectively, before the substrate W completely treated in the exposing apparatus 50 is transferred to the developing block 30b, the additional process chamber 4200 may perform a predetermined additional process on the substrate W. According to an embodiment, the additional process may be an edge exposing process of exposing an edge region of the substrate W to light, a top-side cleaning process of cleaning the top side of the substrate W, or a backside cleaning process of cleaning the backside of the substrate W. A plurality of additional process chambers 4200 may be provided. The additional process chambers 4200 may be stacked one above another. The additional process chambers 4200 may all perform the same process. Selectively, some of the additional process chambers 4200 may perform different processes.

The interface buffer 4400 provides a space in which the substrate W transferred between the coating block 30a, the additional process chambers 4200, the exposing apparatus 50, and the developing block 30b temporarily stays. A plurality of interface buffers 4400 may be provided. The interface buffers 4400 may be stacked one above another.

According to an embodiment, the additional process chambers 4200 may be disposed on one side of an extension line facing the lengthwise direction of the transfer chamber 3400, and the interface buffers 4400 may be disposed on an opposite side of the extension line.

The transfer member 4600 transfers the substrate W between the coating block 30a, the additional process chambers 4200, the exposing apparatus 50, and the developing block 30b. The transfer member 4600 may be implemented with one or more robots. According to an embodiment, the transfer member 4600 has the first robot 4602 and a second robot 4606. The first robot 4602 may transfer the substrate W between the coating block 30a, the additional process chambers 4200, and the interface buffers 4400. An interface robot 4604 may transfer the substrate W between the interface buffers 4400 and the exposing apparatus 50. The second robot 4606 may transfer the substrate W between the interface buffers 4400 and the developing block 30b.

The first robot 4602 and the second robot 4606 each include a hand on which the substrate W is placed, and the hand is movable forward and backward, rotatable about an axis parallel to the third direction 16, and movable along the third direction 16.

The hands of the index robot 2200, the first robot 4602, and the second robot 4606 may all have the same shape as the hand 3420 of the transfer robot 3422. Selectively, a hand of a robot that directly exchanges the substrate W with a transfer plate 3240 of each heat treatment chamber 3200 may have the same shape as the hand 3420 of the transfer robot 3422, and hands of the remaining robots may have a different shape from the hand 3420 of the transfer robot 3422.

According to an embodiment, the index robot 2200 may directly exchange the substrate W with a heating unit 3230 of the front heat treatment chamber 3200 provided in the coating block 30a.

Furthermore, the transfer robots 3422 provided in the coating block 30a and the developing block 30b may directly exchange the substrate W with the transfer plate 3240 located in the heat treatment chamber 3200.

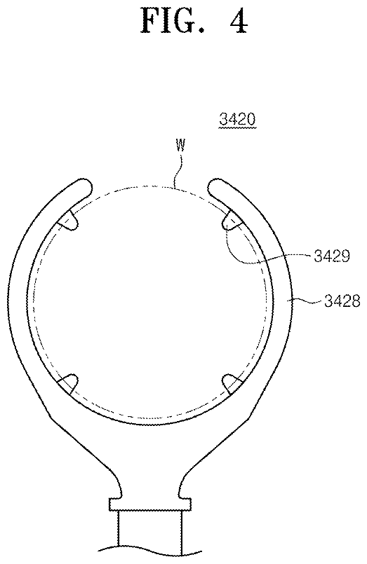

FIG. 4 is a view illustrating one example of the hand of the transfer robot of FIG. 3. Referring to FIG. 4, the hand 3420 has a base 3428 and support protrusions 3429. The base 3428 may have an annular ring shape, the circumference of which is partly curved. The base 3428 has an inner diameter larger than the diameter of the substrate W. The support protrusions 3429 extend inward from the base 3428. The support protrusions 3429 support the edge region of the substrate W. According to an embodiment, four support protrusions 3429 may be provided at equal intervals.

The heat treatment chambers 3200 are arranged along the first direction 12. The heat treatment chambers 3200 are located on one side of the transfer chamber 3400.

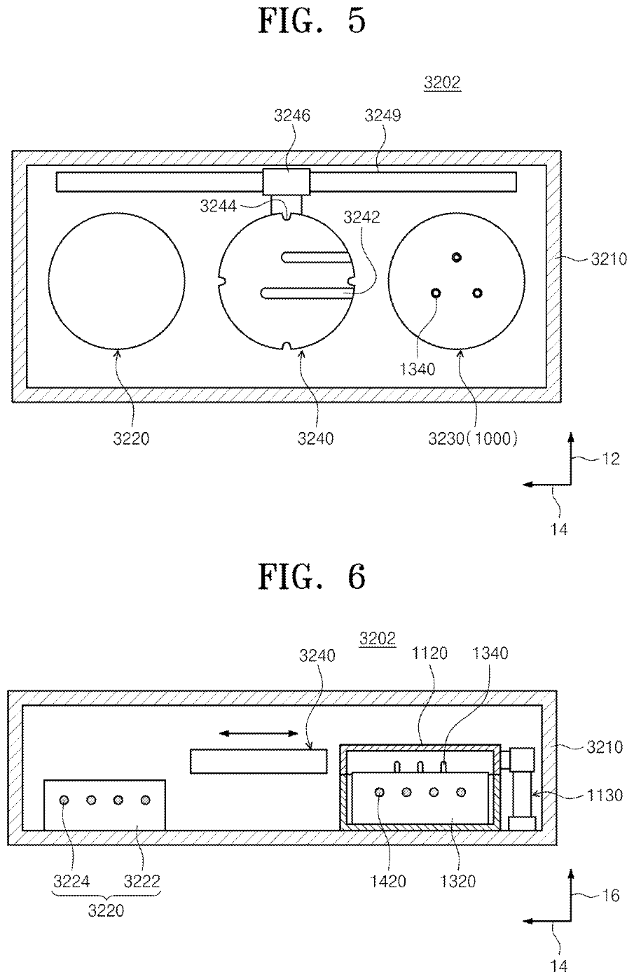

FIG. 5 is a schematic plan view illustrating one example of the heat treatment chamber of FIG. 3, and FIG. 6 is a front view of the heat treatment chamber of FIG. 3. Referring to FIGS. 5 and 6, the heat treatment chamber 3200 has a housing 3210, a cooling unit 3220, the heating unit 3230, and the transfer plate 3240.

The housing 3210 has a substantially rectangular parallelepiped shape. The housing 3210 has, in a sidewall thereof, an entrance/exit opening (not illustrated) through which the substrate W enters and exits the housing 3210. The entrance/exit opening may remain open. Selectively, a door (not illustrated) may be provided to open and close the entrance/exit opening. The cooling unit 3220, the heating unit 3230, and the transfer plate 3240 are provided in the housing 3210. The cooling unit 3220 and the heating unit 3230 are provided side by side along the second direction 14. According to an embodiment, the cooling unit 3220 may be located closer to the transfer chamber 3400 than the heating unit 3230.

The cooling unit 3220 has a cooling plate 3222. The cooling plate 3222 may have a substantially circular shape when viewed from above. A cooling member 3224 is provided inside the cooling plate 3222. According to an embodiment, the cooling member 3224 may be formed inside the cooling plate 3222 and may serve as a fluid channel through which a cooling fluid flows.

The heating unit 3230 is provided as an apparatus 1000 that heats the substrate W above room temperature. The heating unit 3230 heats the substrate W in an atmospheric atmosphere or in an atmosphere of reduced pressure lower than the atmospheric pressure.

The transfer plate 3240 has a substantially circular plate shape and has a diameter corresponding to that of the substrate W. The transfer plate 3240 has notches 3244 formed at the edge thereof. The notches 3244 may have a shape corresponding to the protrusions 3429 formed on the hand 3420 of the transfer robot 3422 described above. Furthermore, as many notches 3244 as the protrusions 3429 formed on the hand 3420 are formed in positions corresponding to the protrusions 3429. The substrate W is transferred between the hand 3420 and the transfer plate 3240 when the vertical positions of the hand 3420 and the transfer plate 3240 aligned with each other in the up/down direction are changed. The transfer plate 3240 may be mounted on a guide rail 3249 and may be moved between a first region 3212 and a second region 3214 along the guide rail 3249 by an actuator 3246. A plurality of guide grooves 3242 in a slit shape are formed in the transfer plate 3240. The guide grooves 3242 extend inward from the edge of the transfer plate 3240. The lengthwise direction of the guide grooves 3242 is parallel to the second direction 14, and the guide grooves 3242 are located to be spaced apart from each other along the first direction 12. The guide grooves 3242 prevent the transfer plate 3240 and lift pins 1340 from interfering with each other when the substrate W is transferred between the transfer plate 3240 and the heating unit 3230.

The substrate W is heated in a state of being directly placed on the transfer plate 3240. The substrate W is cooled in a state in which the transfer plate 3240 on which the substrate W is placed is brought into contact with the cooling plate 3222. The transfer plate 3240 is formed of a material having a high heat transfer rate for efficient heat transfer between the cooling plate 3222 and the substrate W. According to an embodiment, the transfer plate 3240 may be formed of a metallic material.

The heating units 3230 provided in some of the heat treatment chambers 3200 may improve adhesion of photoresist to the substrate W by supplying a gas while heating the substrate W. According to an embodiment, the gas may be a hexamethyldisilane gas.

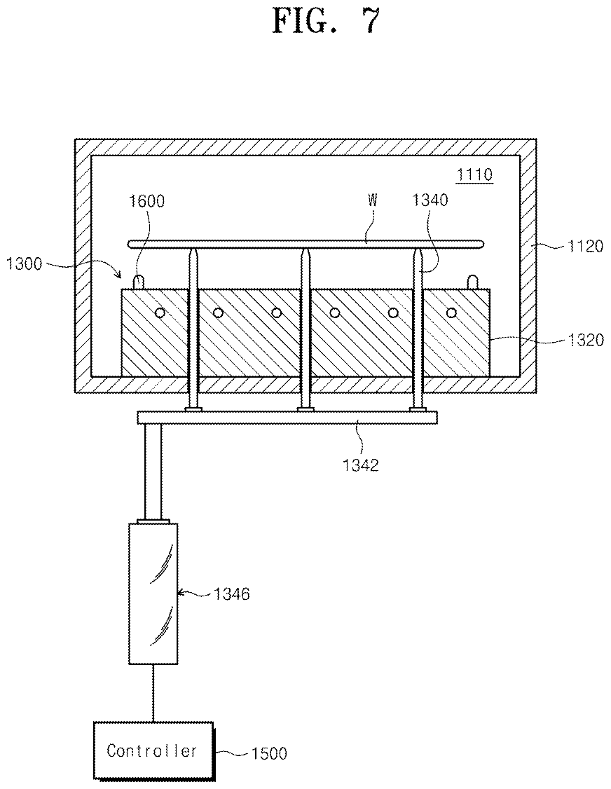

FIG. 7 is a sectional view illustrating the heating unit of FIG. 6. Referring to FIG. 7, the heating unit 3230 includes a chamber 1120, a support unit 1300, the lift pins 1340, a drive member 1346, a heater unit 1420, and a controller 1500.

The chamber 1120 has a treatment space 1110 in which heat treatment is performed on the substrate W. The treatment space 1110 is hermetically sealed from the outside.

The support unit 1300 supports the substrate W in the treatment space 1110. The support unit 1300 includes a support plate 1320, the lift pins 1340, and proximity pins 1600. The support plate 1320 transfers, to the substrate W, heat generated from the heater unit 1420. In an embodiment, the support plate 1320 has a circular plate shape. An upper surface of the support plate 1320 has a larger diameter than the substrate W. The upper surface of the support plate 1320 functions as a seating surface on which the substrate W is placed. A plurality of lift holes are formed in the seating surface.

The lift pins 1340 raise or lower the substrate W over the support plate 1320. The lift pins 1340 have a pin shape facing the vertical direction. The lift pins 1340 may be mounted on a single plate 1342. The lift pins 1340 are located in the lift holes, respectively.

The drive member 1346 moves the lift pins 1340 between a raised position and a lowered position. Here, the raised position is defined as a position in which upper ends of the lift pins 1340 are in a higher position than the seating surface, and the lowered position is defined as a position in which the upper ends of the lift pins 1340 are at the same height as, or in a lower position than, the seating surface. The drive member 1346 may be located outside the chamber 1120. In an embodiment, the drive member 1346 may be a motor.

The proximity pins 1600 prevent the substrate W from making direct contact with the support plate 1320. The proximity pins 1600 have a pin shape having a lengthwise direction parallel to the lift pins 1340. The proximity pins 1600 are fixedly installed on the seating surface of the support plate 1320. The proximity pins 1600 are located to protrude upward from the seating surface. Upper ends of the proximity pins 1600 are provided as contact surfaces making direct contact with the bottom of the substrate W, and the contact surfaces have a shape that is convex upward. Accordingly, contact areas between the proximity pins 1600 and the substrate W may be minimized.

The heater unit 1420 heats the substrate W placed on the support plate 1320. The heater unit 1420 is located under the substrate W placed on the support plate 1320. In an embodiment, the heater unit 1420 includes a plurality of heaters. The heaters are located inside the support plate 1320. Selectively, the heaters may be located on the bottom of the support plate 1320. The heaters are located on the same plane.

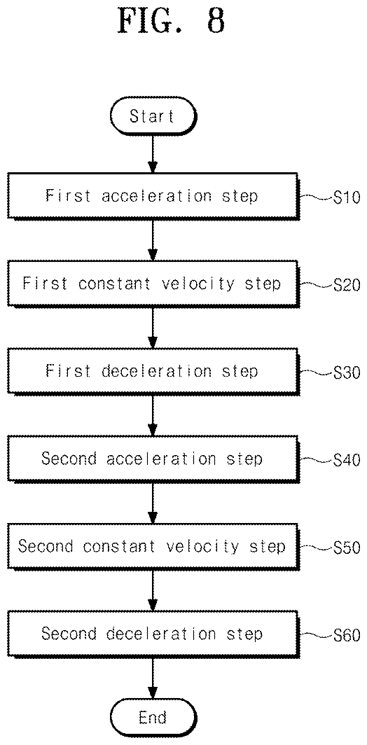

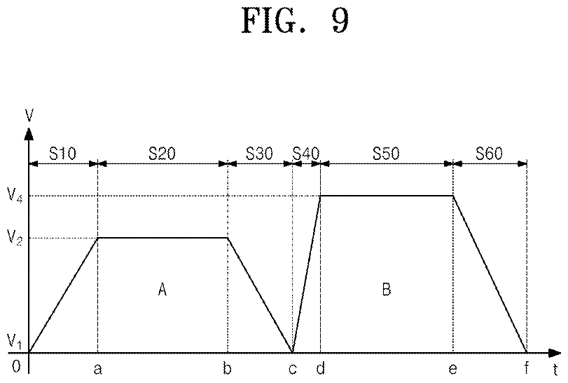

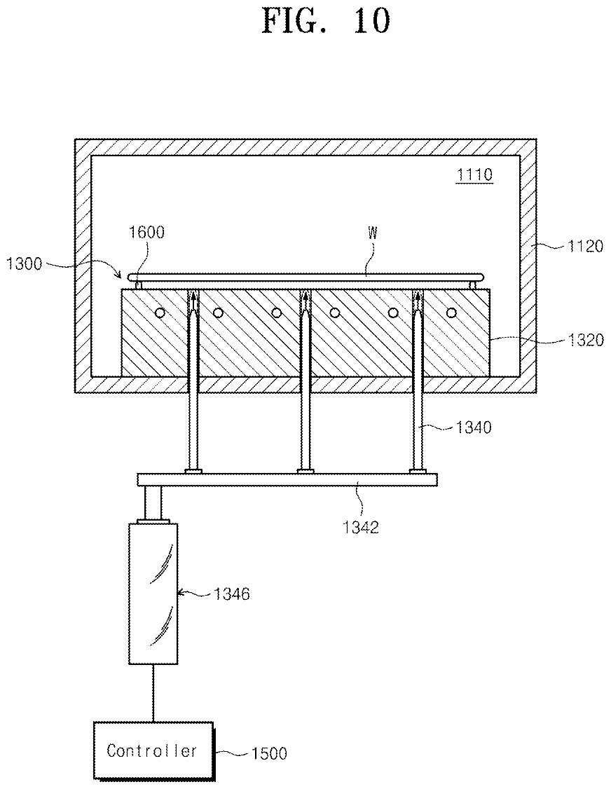

Hereinafter, a substrate lifting method of the inventive concept will be described in detail with reference to FIGS. 8 to 13. The controller 1500 controls the drive member 1346 to perform the substrate lifting method of the inventive concept. FIG. 8 is a flowchart illustrating the substrate lifting method of the inventive concept. FIG. 9 is a graph depicting a moving velocity of the lift pins 1340 according to the substrate lifting method of the inventive concept. FIGS. 10 to 13 are views illustrating the substrate lifting method of the inventive concept in sequence. The moving velocity of the lift pins 1340 illustrated in FIG. 9 refers to a velocity that the controller 1500 inputs to cause the drive member 1346 to move the lift pins 1340.

Referring to FIGS. 8 and 9, the substrate lifting method of the inventive concept includes first acceleration step S10, first constant velocity step S20, first deceleration step S30, second acceleration step S40, second constant velocity step S50, and second deceleration step S60. Through first acceleration step S10 to second deceleration step S60, the lift pins 1340 raise the substrate W off the support plate 1320 while vertically moving from the lowered position to the raised position.

First, the lift pins 1340 are located in the lift holes. In first acceleration step S10, the lift pins 1340 are vertically moved toward the substrate W supported on the proximity pins 1600. In first acceleration step S10, the lift pins 1340 are accelerated at a first acceleration from a first velocity V1 to a second velocity V2 higher than the first velocity V1.

In an embodiment, the first velocity V1 is 0. That is, the lift pins 1340 are at rest when first acceleration step S10 starts. Referring to FIG. 10, in first acceleration step S10, the lift pins 1340 at rest in the lift holes are accelerated to a position where the lift pins 1340 are not brought into contact with the substrate W.

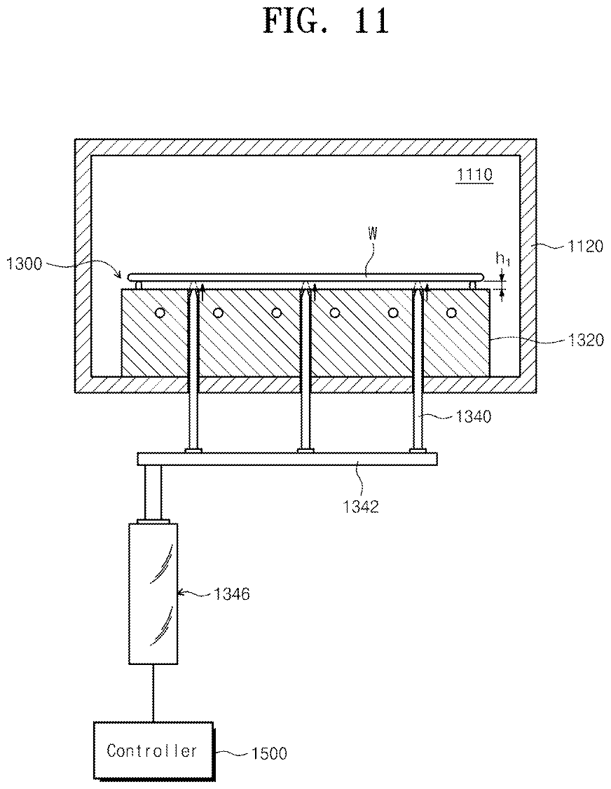

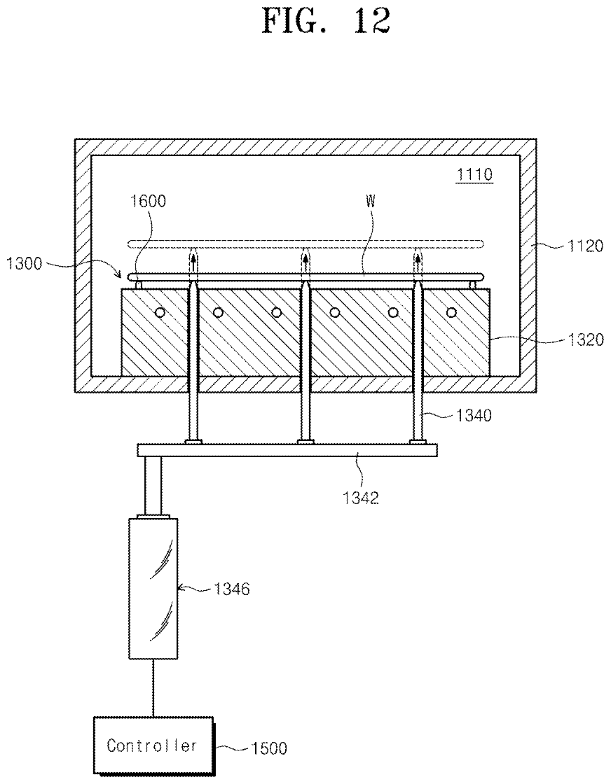

After first acceleration step S10, in first constant velocity step S20, the lift pins 1340 are uniformly moved at the second velocity V2. In first deceleration step S30 after the lift pins 1340 are uniformly moved at the second velocity V2, the lift pins 1340 are decelerated at a first deceleration from the second velocity V2 to a third velocity V3 lower than the second velocity V2. Selectively, after first acceleration step S10, first deceleration step S30 may be performed without first constant velocity step S20. In an embodiment, as illustrated in FIG. 11, in first deceleration step S30, the lift pins 1340 are brought into contact with the substrate W. As the lift pins 1340 are decelerated when the lift pins 1340 are brought into contact with the substrate W, there is an advantage of reducing a squeeze effect.

The lift pins 1340 and the substrate W are brought into contact with each other in the position where the proximity pins 1600 support the substrate W. In an embodiment, the lift pins 1340 and the substrate W are brought into contact with each other at a distance of ht from the support plate 1320. At this time, the third velocity V3, which is the velocity of the lift pins 1340, is 0. After the contact of the lift pins 1340 with the substrate W, second acceleration step S40, second constant velocity step S50, and second deceleration step S60 are performed in sequence.

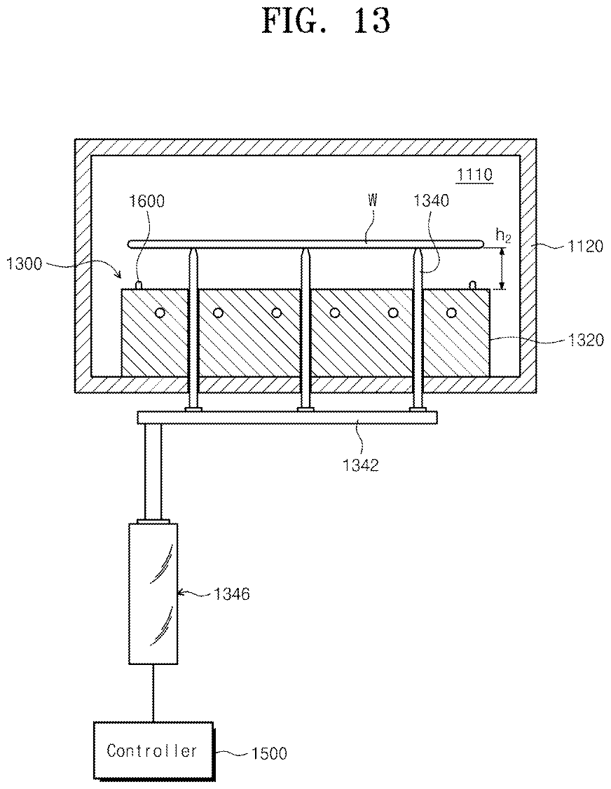

As illustrated in FIG. 12, in second acceleration step S40, the lift pins 1340 vertically raise the substrate W in the state of being brought into contact with the bottom of the substrate W. In second acceleration step S40, the lift pins 1340 are accelerated at a second acceleration from the third velocity V3 to a fourth velocity V4 higher than the third velocity V3. In an embodiment, the second acceleration may be greater than the first acceleration. Thereafter, in second constant velocity step S50, the lift pins 1340 are uniformly moved at the fourth velocity V4. In second deceleration step S60 after the lift pins 1340 are uniformly moved at the fourth velocity V4, the lift pins 1340 are decelerated at a second deceleration from the fourth velocity V4 to a fifth velocity V5 lower than the fourth velocity V4. Selectively, after second acceleration step S40, second deceleration step S60 may be performed without second constant velocity step S50. The fifth velocity V5 is 0, and when second deceleration step S60 is completed, the lift pins 1340 stop.

As illustrated in FIG. 13, through second acceleration step S40 to second deceleration step S60, the lift pins 1340 raise the substrate W to a distance of h2 from the support plate 1320.

In the above-described embodiment, it has been described that the lift pins 1340 make contact with the substrate W in first deceleration step S30. However, in another embodiment, the lift pins 1340 may make contact with the substrate W in first constant velocity step S20.

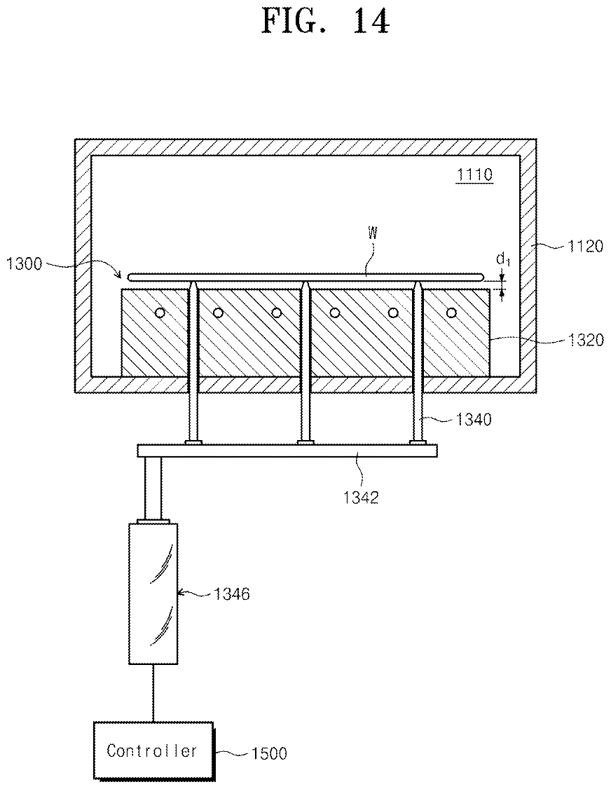

In the above-described embodiment, it has been described that the support unit 1300 includes the proximity pins 1600 and the proximity pins 1600 support the substrate W at the distance of h1 from the support plate 1320. However, in another embodiment, the support unit 1300 may not include the proximity pins 1600. As illustrated in FIG. 14, the lift pins 1340 may support the substrate W at a distance of d1 from the support plate 1320. For example, d1 may be equal to h1 of FIG. 11.

Thereafter, first acceleration step S10, first constant velocity step S20, first deceleration step S30, second acceleration step S40, second constant velocity step S50, and second deceleration step S60, which have been described above, may be performed.

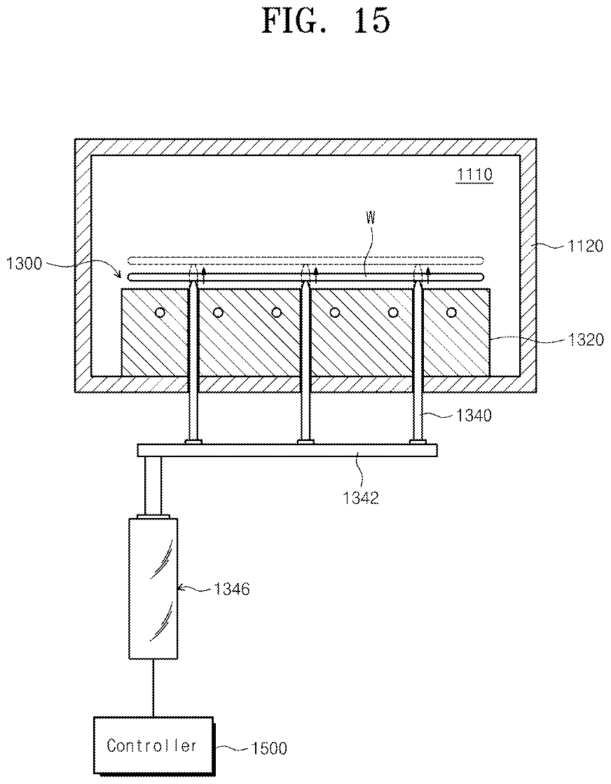

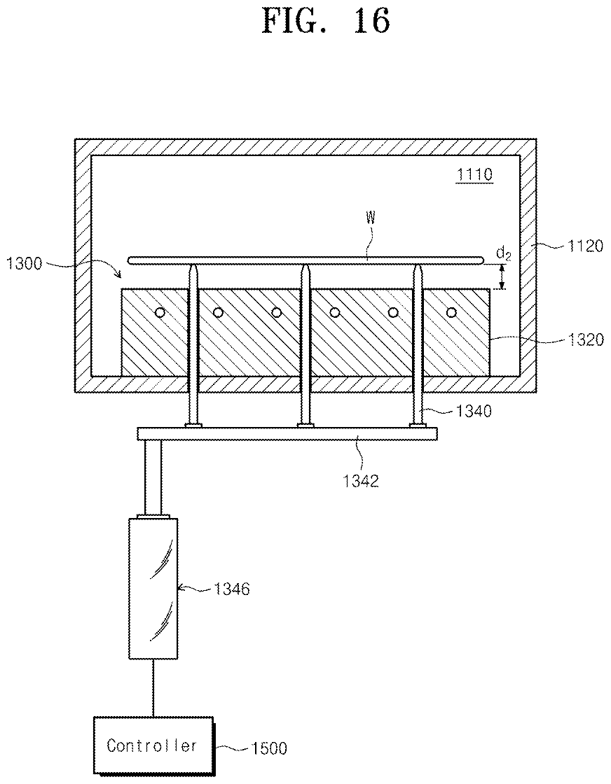

As illustrated in FIGS. 15 and 16, the lift pins 1340 are moved upward to a distance of d2 from the support plate 1320. In an embodiment, first acceleration step S10, first constant velocity step S20, and first deceleration step S30 may be performed while the substrate W is moved from the position spaced apart from the support plate 1320 by d1 to the position spaced apart from the support plate 1320 by d2. For example, the difference between d1 and d2 may be a distance corresponding to the area “A” illustrated in FIG. 9. In an embodiment, d2 may be set to a distance by which a squeeze effect does not occur when the substrate W is spaced apart from the support plate 1320.

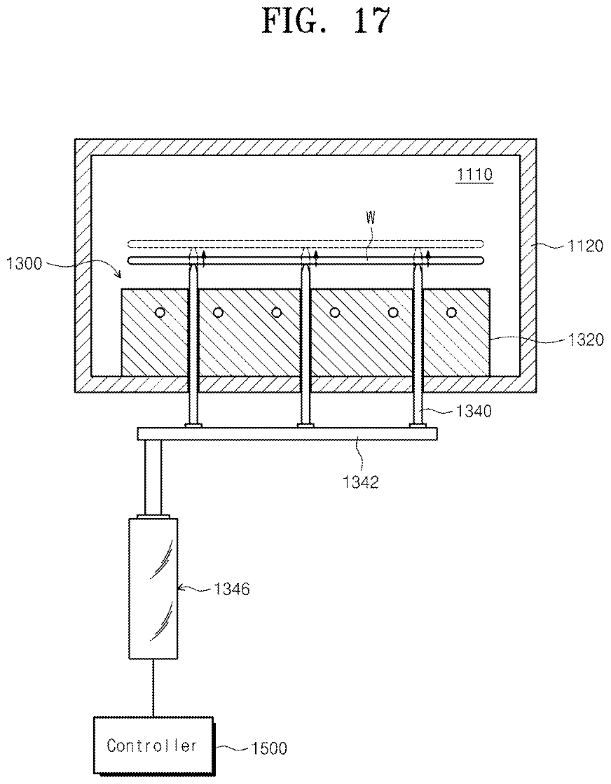

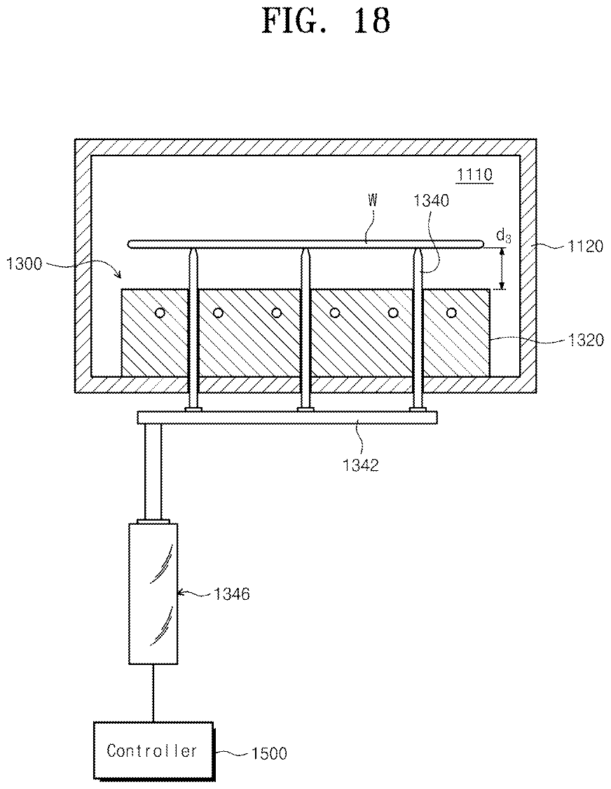

Thereafter, as illustrated in FIGS. 17 and 18, the lift pins 1340 are moved upward to a distance of d3 from the support plate 1320. In an embodiment, second acceleration step S40, second constant velocity step S50, and second deceleration step S60 may be performed while the substrate W is moved from the position spaced apart from the support plate 1320 by d2 to the position spaced apart from the support plate 1320 by d3. For example, the difference between d2 and d3 may be a distance corresponding to the area “B” illustrated in FIG. 9.

According to the inventive concept, the drive member 1346 that drives the lift pins 1340 is implemented with a motor. Accordingly, the stroke of the lift pins 1340 may be provided as various distances. Furthermore, the driving velocity of the lift pins 1340 may be easily adjusted, and accuracy in driving the lift pins 1340 may be improved. In addition, there is an advantage of reducing costs by removing the proximity pins 1600 as illustrated in FIG. 14.

According to the inventive concept, the second acceleration is greater than the first acceleration, and therefore time spent moving the lift pins 1340 from the lowered position to the raised position may be reduced.

According to the inventive concept, the lift pins 1340 are accelerated in first acceleration step S10, and therefore time spent moving the lift pins 1340 from the lowered position to the raised position may be reduced.

According to the inventive concept, the third velocity V3 is 0 in first deceleration step S30, and therefore a deceleration interval may be ensured in an actual movement of the lift pins 1340.

According to the embodiments of the inventive concept, there is an advantage of minimizing occurrence of a squeeze effect during operation of lift pins.

Effects of the inventive concept are not limited to the aforementioned effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for treating a substrate, the apparatus comprising:
a support plate on which the substrate is placed;
a lift pin configured to load the substrate onto the support plate or unload the substrate from the support plate;
a drive member configured to raise or lower the lift pin; and
a controller configured to control operation of the drive member,
wherein the controller controls the drive member to:
raise the substrate off the support plate while vertically moving the lift pin between a lowered position spaced apart downward from the support plate by a first distance and a raised position spaced apart from upward from the support plate by a second distance; and
bring the lift pin into contact with the substrate while the lift pin is decelerated or moved at a constant velocity.

2. The apparatus of claim 1, wherein the controller controls the drive member to:
accelerate the lift pin at a first acceleration from a first velocity to a second velocity higher than the first velocity;
decelerate the lift pin at a first deceleration from the second velocity to a third velocity lower than the second velocity; and
bring the lift pin into contact with the substrate when the lift pin is decelerated.

3. The apparatus of claim 1, wherein the controller controls the drive member to:
accelerate the lift pin at a first acceleration from a first velocity to a second velocity higher than the first velocity;
uniformly move the lift pin at the second velocity;
decelerate the lift pin at a first deceleration from the second velocity to a third velocity lower than the second velocity; and
bring the lift pin into contact with the substrate when the lift pin is decelerated.

4. The apparatus of claim 3, wherein the controller controls the drive member to:
accelerate the lift pin at a second acceleration from the third velocity to a fourth velocity higher than the third velocity after decelerating the lift pin at the first deceleration; and
decelerate the lift pin at a second deceleration from the fourth velocity to a fifth velocity lower than the fourth velocity.

5. The apparatus of claim 3, wherein the controller controls the drive member to:
accelerate the lift pin at a second acceleration from the third velocity to a fourth velocity higher than the third velocity after decelerating the lift pin at the first deceleration;
uniformly move the lift pin at the fourth velocity; and
decelerate the lift pin at a second deceleration from the fourth velocity to a fifth velocity lower than the fourth velocity.

6. The apparatus of claim 4, wherein the second acceleration is greater than the first acceleration.

7. The apparatus of claim 2, wherein the first velocity is 0.

8. The apparatus of claim 2, wherein the third velocity is 0.

9. The apparatus of claim 4, wherein the fifth velocity is 0.

10. The apparatus of claim 1, wherein the drive member is a motor.
